(19) United States
(12) Patent Application Publication
(10) Pub. No.: US 2025/0381767 A1
(43) Pub. Date: Dec. 18, 2025

(54) BONDING DEVICE AND METHOD OF MANUFACTURING DISPLAY DEVICE USING THE SAME

(71) Applicant: Samsung Display Co., Ltd., Yongin-si (KR)

(72) Inventors: DONGJIN PARK, Yongin-si (KR); YOUNGSU KIM, Yongin-si (KR); CHEULJIN PARK, Yongin-si (KR); KISANG YOO, Yongin-si (KR); SANGHYUCK YOON, Yongin-si (KR); SUNGKOOK LEE, Yongin-si (KR); JAESANG LEE, Yongin-si (KR)

(21) Appl. No.: 19/079,016

(22) Filed: Mar. 13, 2025

(30) Foreign Application Priority Data
Jun. 13, 2024 (KR) 10-2024-0077131

(51) Int. Cl. B32B 37/00; B32B 37/10; B32B 38/18; H10K 59/12; H10K 59/80; H10K 71/50

(52) U.S. Cl. CPC B32B 37/0046; B32B 37/10; B32B 38/1833; H10K 59/1201; H10K 59/8722; H10K 71/50; B32B 2250/02; B32B 2457/206

(57) ABSTRACT

A bonding device includes: a pressure pad; a jig below the pressure pad; and a moving part below the jig, wherein the jig includes: a first jig; and a plurality of second jigs adjacent to the first jig, and wherein the moving part includes: a first moving part below the first jig; and a plurality of second moving parts respectively below the second jigs.

### CROSS-REFERENCE TO RELATED APPLICATION

The present application claims priority to and the benefit of Korean Patent Application No. 10-2024-0077131, filed on Jun. 13, 2024, in the Korean Intellectual Property Office, the entire disclosure of which is incorporated herein by reference.

### BACKGROUND

Aspects of some embodiments of the present disclosure herein relate to a bonding device and a method of manufacturing a display device using the same.

Electronic devices, such as smart phones, digital cameras, laptop computers, navigation systems, and smart televisions, which provide images to users, include a display device for displaying images. The display device generates images and provides them to users through a display screen.

The above information disclosed in this Background section is only for enhancement of understanding of the background and therefore the information discussed in this Background section does not necessarily constitute prior art.

### SUMMARY

Aspects of some embodiments of the present disclosure include a bonding device, which may prevent or reduce bonding defects between a display module and a window, and a method of manufacturing a display device using the same.

Recently, with the development of display device technology, various types of display devices are being developed. For example, a display device, which has a curved surface on its side and displays images on a portion of the curved surface, is being developed.

The display device includes a display module, which displays images, and a window located on the display module to protect the display module. When the side of the display device has a curved surface, the side of the display module and the side of the window also have a curved surface. In order to bond the display module and the window to each other, technology development is required to easily bond the side of the display module having a curved surface and the side of the window having a curved surface to each other.

Aspects of some embodiments of the present disclosure include a bonding device including a pressure pad, a jig below the pressure pad, and a moving part below the jig, wherein the jig may include a first jig and a plurality of second jigs adjacent to the first jig, and the moving part may include a first moving part below the first jig and a plurality of second moving parts respectively below the second jigs.

According to some embodiments of the present disclosure, a bonding device includes a pressure pad and a jig below the pressure pad, wherein the jig presses the pressure pad and the jig may include: a first jig which moves in an up-and-down direction and defines a central pressing axis when the pressure pad is pressed; and a plurality of second jigs which respectively define the corners of the jig, move in an up-and-down direction, and define corner pressing axes adjacent to the corners of the jig when the pressure pad is pressed.

According to some embodiments of the present disclosure, a method of manufacturing a display device includes: arranging a display module on a pressure pad on a jig including a first jig and a plurality of second jigs adjacent to the first jig; arranging a window on the display module; moving the jig upward to press the pressure pad and bonding the display module to the window; and moving the second jigs further upward to press the round corner portions of the pressure pad overlapping the second jigs and bonding the first round corner portions of the display module to the second round corner portions of the window.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view of a display device manufactured by using a bonding device according to some embodiments of the present disclosure;

FIG. 2 is a schematic cross-sectional view of a display module and a window of the display device illustrated in FIG. 1;

FIG. 3 illustrates a cross section of the display module illustrated in FIG. 2;

FIG. 4 illustrates a cross section of the display panel illustrated in FIG. 3;

FIG. 5 is a perspective view of a bonding device according to some embodiments of the present disclosure;

FIG. 6 is an exploded perspective view of a jig and a pressure pad illustrated in FIG. 5;

FIG. 7 is a plan view of the jig illustrated in FIG. 6;

FIG. 8 is a plan view of the pressure pad illustrated in FIG. 6 and viewed from above;

FIG. 9A is a cross-sectional view taken along the line I-I′ illustrated in FIG. 6;

FIG. 9B is a cross-sectional view taken along the line II-II′ illustrated in FIG. 6;

FIG. 9C is a cross-sectional view taken along the line III-III′ illustrated in FIG. 6;

FIG. 10 illustrates a state in which the display module is located on the pressure pad for a bonding process between the display module and the window;

FIGS. 11A, 11B, and 11C are cross-sectional views of the bonding device, which correspond to FIGS. 9A, 9B, and 9C, in a preparation step illustrated in FIG. 10;

FIG. 12 is a plan view of the display module and a guide film illustrated in FIGS. 11A to 11C and viewed from above;

FIG. 13 illustrates a state in which a window fixing chuck and a pressure pad are arranged to be adjacent to each other;

FIG. 14 is a view in which the window fixing chuck of FIG. 13 is omitted;

FIG. 15 illustrates a first bonding process between the display module and the window by using a bonding device in a method of manufacturing the display device with the use of the bonding device;

FIGS. 16A, 16B, and 16C are cross-sectional views of the bonding device, which correspond to FIGS. 11A, 11B, and 11C, in the first bonding process illustrated in FIG. 15;

FIG. 17 is a plan view illustrating a deformed state of the pressure pad in the first bonding process illustrated in FIGS. 16A, 16B, and 160;

FIG. 18 illustrates a second bonding process between the display module and the window by using a bonding device in a method of manufacturing the display device with the use of the bonding device;

FIG. 19 is a cross-sectional view of the bonding device, which corresponds to FIG. 16C, in the second bonding process illustrated in FIG. 18;

FIG. 20 illustrates a first bonding process by using a bonding device according to some embodiments of the present disclosure;

FIGS. 21A, 21B, and 21C are cross-sectional views of the bonding device, which correspond to FIGS. 16A, 16B, and 16C, in the first bonding process illustrated in FIG. 20;

FIG. 22 illustrates a second bonding process by using the bonding device according to some embodiments of the present disclosure;

FIG. 23 is a cross-sectional view of the bonding device, which corresponds to FIG. 21C, in the second bonding process illustrated in FIG. 22;

FIG. 24 illustrates the configuration of a bonding device according to some embodiments of the present disclosure;

FIG. 25 illustrates the configuration of a bonding device according to some embodiments of the present disclosure; and

FIG. 26 is a plan view of a jig illustrated in FIG. 25.

### DETAILED DESCRIPTION

In this specification, it will be understood that when an element (or region, layer, part, etc.) is referred to as being “on”, “connected to” or “coupled to” another element, it can be directly on, connected or coupled to the other element, or intervening elements may be present.

Like reference numerals refer to like elements throughout. In addition, in the drawings, the thicknesses, ratios, and dimensions of elements are exaggerated for effective description of the technical contents.

As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that the terms “include” and/or “have”, when used in this specification, specify the presence of stated features, integers, steps, operations, elements, components and/or combinations thereof, but do not preclude the presence or addition of one or more other features, integers, steps, operations, elements, components, and/or combinations thereof.

Hereinafter, aspects of some embodiments of the present disclosure will be described with reference to the accompanying drawings.

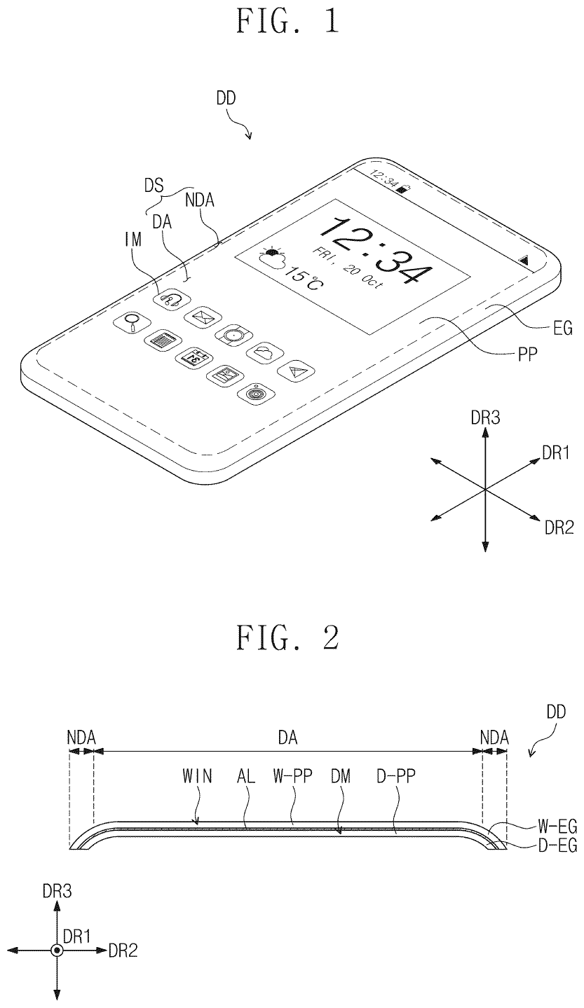

FIG. 1 is a perspective view of a display device manufactured by using a bonding device according to some embodiments of the present disclosure.

Referring to FIG. 1, the display device DD according to some embodiments of the present disclosure may have long sides extending in parallel to a first direction DR1 and have short sides extending in parallel to a second direction DR2 crossing the first direction DR1. The corners of the display device DD connecting the long and short sides of the display device DD to each other may have curved shapes. The corners of the display device DD having curved shapes may be defined as round corners. The shape of the display device DD may be defined as a round-cornered tetragon.

Hereinafter, a direction that perpendicularly (or substantially perpendicularly) crosses a plane defined by the first direction DR1 and the second direction DR2 is defined as a third direction DR3. In this specification, the expressions “when viewed on a plane” or “in a plan view” may refer to a state of being viewed from the third direction DR3.

Images IM generated in the display device DD may be provided or displayed to users through the upper surface of the display device DD which is viewed from the third direction DR3. The upper surface of the display device DD may include a display region DA and a non-display region NDA surrounding (e.g., in a periphery or outside a footprint of) the display region DA. The display region DA may display images, and the non-display region NDA may not display images. The non-display region NDA may surround the display region DA and define a boundary of the display device DD printed in a color (e.g., a set or predetermined color).

The upper surface of the display device DD may include a flat planar portion PP and an edge portion EG having a curved surface. The planar portion PP may have a plane defined by the first and second directions DR1 and DR2. The edge portion EG may surround the planar portion PP. The edge portion EG may extend downward from the planar portion PP so as to form a curved surface. The edge portion EG may have a curvature (e.g., a set or predetermined curvature). The display region DA may be defined in the planar portion PP and a portion of the edge portion EG adjacent to the planar portion PP (This will be illustrated more clearly in FIGS. 2 to 4 below).

As an example, the display device DD is illustrated as a mobile phone, but without being limited thereto, the display device DD may be used for various electronic devices. For example, the display device DD may be used for large electronic devices such as televisions, monitors, or external billboards. In addition, the display device DD may be used for small and medium-sized electronic devices such as personal computers, laptop computers, car navigation systems, game consoles, tablets, or cameras.

FIG. 2 is a schematic cross-sectional view of a display module and a window of the display device illustrated in FIG. 1.

As an example, FIG. 2 illustrates a cross section of a display module DM and a window WIN viewed from the first direction DR1.

Referring to FIG. 2, the display device DD may include a display module DM and a window WIN located on the display module DM. The window WIN may protect the display module DM from external scratches and impacts.

The display module DM may include a flat planar portion D-PP and an edge portion D-EG extending from the planar portion D-PP and having a curved surface. The window WIN may include a flat planar portion W-PP and an edge portion W-EG extending from the planar portion W-PP and having a curved surface.

In a plan view, the planar portion D-PP of the display module DM and the planar portion W-PP of the window WIN may overlap each other. In a plan view, the edge portion D-EG of the display module DM and the edge portion W-EG of the window WIN may overlap each other.

The planar portion D-PP of the display module DM and the planar portion W-PP of the window WIN may correspond to the planar portion PP of the display device DD. The edge portion D-EG of the display module DM and the edge portion W-EG of the window WIN may correspond to the edge portion EG of the display device DD.

According to some embodiments, the display module DM and window WIN may have a shape corresponding to the display device DD illustrated in FIG. 1. For example, the display module DM and the window WIN may have a round-cornered tetragonal shape corresponding to the display device DD.

An adhesive layer AL may be located between the display module DM and the window WIN. The display module DM and the window WIN may be bonded to each other by the adhesive layer AL. The adhesive layer AL may include a pressure sensitive adhesive (PSA) or an optically clear adhesive (OCA), but the type of adhesive is not limited thereto.

The display region DA may be defined in the planar portion PP and a portion of the edge portion EG adjacent to the planar portion PP. Accordingly, the portion of the edge portion EG adjacent to the planar portion PP may display an image.

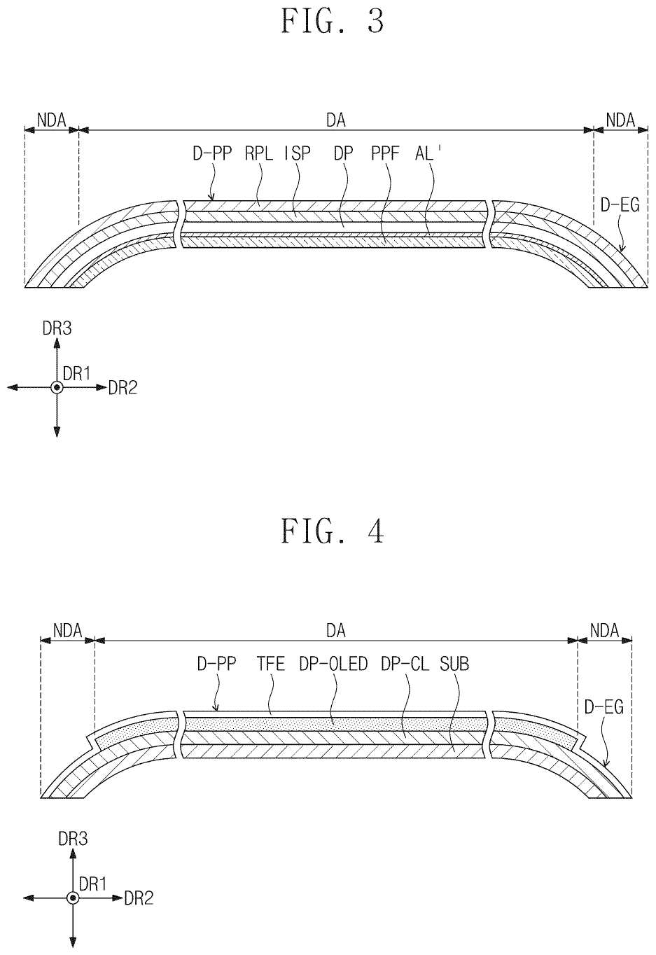

FIG. 3 illustrates a cross section of the display module illustrated in FIG. 2.

As an example, FIG. 3 illustrates a cross section of the display module DM viewed from the first direction DR1.

Referring to FIG. 3, the display module DM may include a display panel DP, an input sensing unit ISP, a reflection prevention layer RPL, a panel protection film PPF, and an adhesive layer AL′.

The display panel DP according to some embodiments of the present disclosure may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots, quantum rods, and the like. Hereinafter, the display panel DP will be described as an organic light-emitting display panel.

The input sensing unit ISP may be located on the display panel DP. The input sensing unit ISP may include a plurality of sensing units for sensing an external input by a capacitive method. The input sensing unit ISP may be manufactured directly on the display panel DP when the display device DD is manufactured. Without being limited thereto, however, the input sensing unit ISP may be manufactured as a panel separate from the display panel DP and then attached to the display panel DP by an adhesive layer.

The reflection prevention layer RPL may be located on the input sensing unit ISP. The reflection prevention layer RPL may be manufactured directly on the input sensing unit ISP when the display device DD is manufactured. Without being limited thereto, however, the reflection prevention layer RPL may be manufactured as a separate panel and then attached to the input sensing unit ISP by an adhesive layer.

The reflection prevention layer RPL may be defined as an external light reflection prevention film. The reflection prevention layer RPL may reduce the reflectance of external light incident from above the display device DD toward the display panel DP. The external light may not be visible to a user due to the reflection prevention layer RPL.

When external light traveling toward the display panel DP is reflected by the display panel DP like a mirror and provided back to an external user, the user may visually recognize the external light. In order to prevent or reduce instances of such a phenomenon, as an example, the reflection prevention layer RPL may include a plurality of color filters that display the same colors as the pixels of the display panel DP.

The color filters may filter external light into the same colors as the pixels PX. In this case, the external light may not be visible to a user. Without being limited thereto, however, the reflection prevention layer RPL may include a retarder and/or a polarizer to reduce the reflectance of external light.

The panel protection film PPF may be located below the display panel DP. The panel protection film PPF may protect the lower portion of the display panel DP. The panel protection film PPF may include a flexible plastic material such as polyethylene terephthalate (PET).

The adhesive layer AL′ may be located between the display panel DP and the panel protection film PPF. The display panel DP and the panel protection film PPF may be bonded to each other by the adhesive layer AL′. The adhesive layer AL′ may include a pressure-sensitive adhesive or an optically clear adhesive, but the type of adhesive is not limited thereto.

FIG. 4 illustrates a cross section of the display panel illustrated in FIG. 3.

As an example, FIG. 4 illustrates a cross section of the display panel DP viewed from the first direction DR1.

Referring to FIG. 4, the display panel DP may include a substrate SUB, a circuit element layer DP-CL located on the substrate SUB, a display element layer DP-OLED located on the circuit element layer DP-CL, and a thin film encapsulation layer TFE located on the display element layer DP-OLED.

The display panel DP may include a flat planar portion D-PP and an edge portion D-EG extending from the planar portion D-PP and having a curved surface. As an example, the planar portion D-PP and the edge portion D-EG of the display panel DP are illustrated with the same symbols as the planar portion D-PP and the edge portion D-EG of the display module DM.

The substrate SUB may include a display region DA and a non-display region NDA surrounding the display region DA. The substrate SUB may include glass or a flexible plastic material such as polyimide (PI).

The display element layer DP-OLED may be located on the display region DA. The display element layer DP-OLED may generate images. The display element layer DP-OLED may be located within the planar portion D-PP and a portion of the edge portion D-EG adjacent to the planar portion D-PP. Accordingly, images may be displayed in a portion of the edge portion D-EG adjacent to the planar portion D-PP.

A plurality of pixels may be located in the circuit element layer DP-CL and the display element layer DP-OLED. Each of the pixels may include a transistor located in the circuit element layer DP-CL and a light-emitting element located in the display element layer DP-OLED and connected to the transistor.

The thin film encapsulation layer TFE may be located on the circuit element layer DP-CL so as to cover the display element layer DP-OLED. The thin film encapsulation layer TFE may protect the pixels from moisture, oxygen, and external foreign substances.

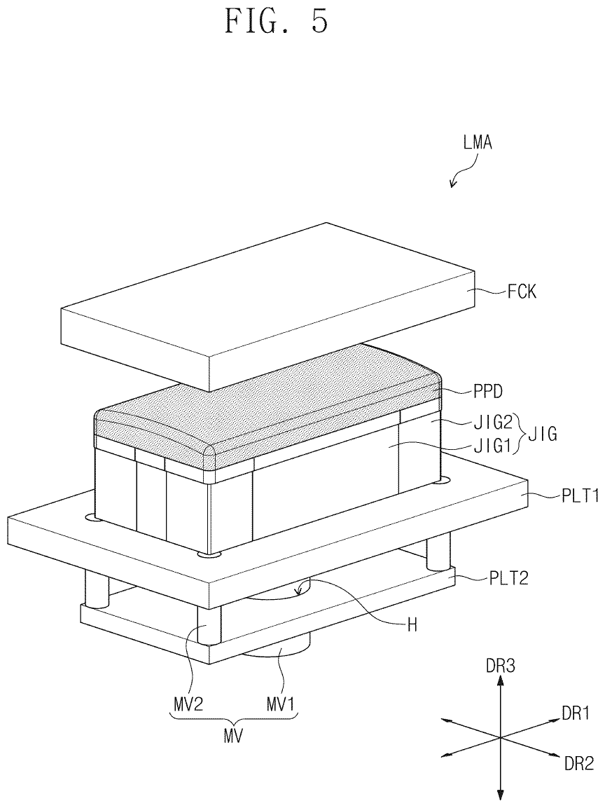

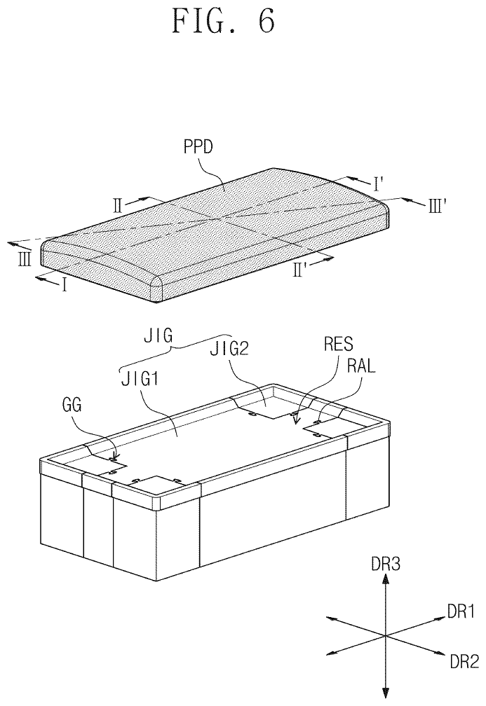

FIG. 5 is a perspective view of a bonding device according to some embodiments of the present disclosure.

Referring to FIG. 5, the bonding device LMA according to some embodiments of the present disclosure may be defined as a laminating device. The bonding device LMA may include a window fixing chuck FCK, a pressure pad PPD, a jig JIG, a first plate PLT1, a second plate PLT2, and a moving part MV.

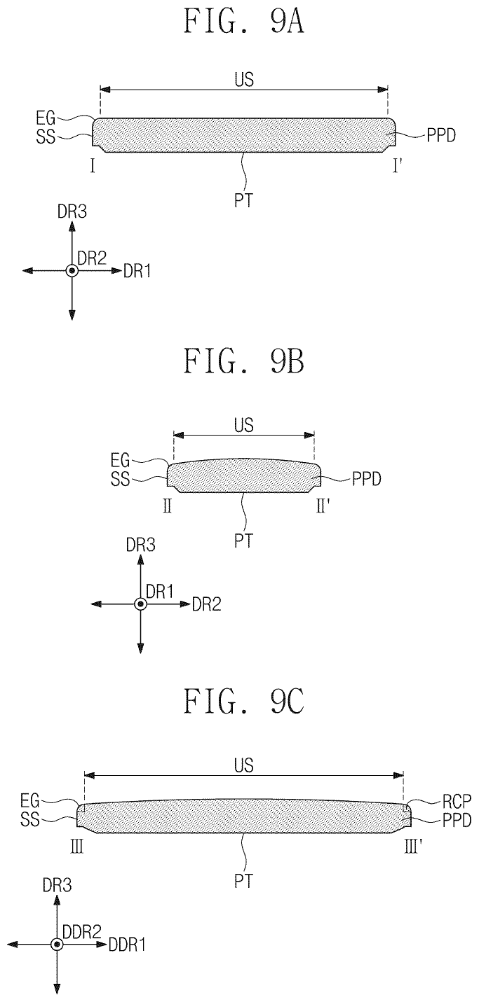

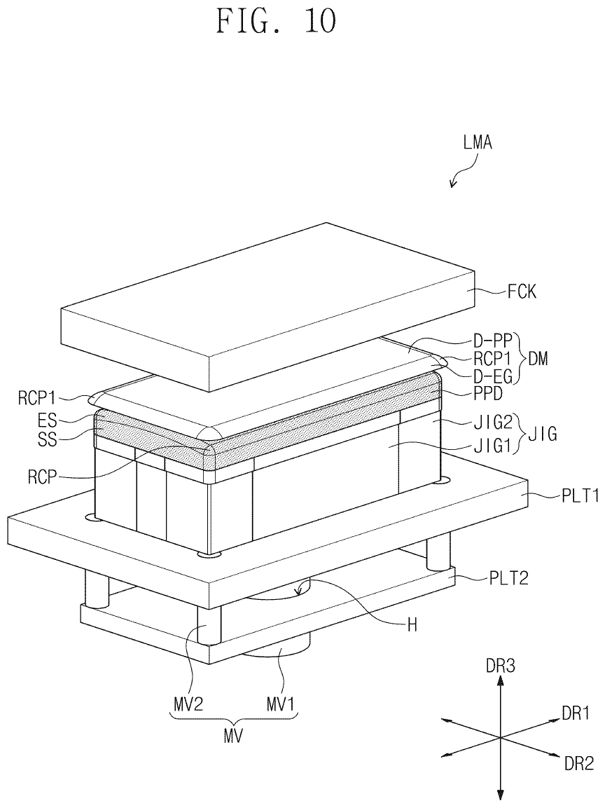

The window fixing chuck FCK may be located on the pressure pad PPD. The window fixing chuck FCK may extend longer in the first direction DR1 than in the second direction DR2. According to some embodiments, a recessed portion may be defined on the lower surface of the window fixing chuck FCK, and the window may be located in the recessed portion. This configuration will be illustrated and described in more detail with respect to FIG. 9A below.

The pressure pad PPD may be located on the jig JIG. The pressure pad PPD may be located between the window fixing chuck FCK and the jig JIG. The pressure pad PPD may extend longer in the first direction DR1 than in the second direction DR2. The pressure pad PPD may include a material having a shape which may be easily deformed and restored. For example, the pressure pad PPD may include rubber, silicone, or polyurethane, but the material of the pressure pad PPD is not limited thereto.

The jig may be located below the pressure pad PPD. The jig may extend longer in the first direction DR1 than in the second direction DR2. The jig JIG may include a first jig JIG1 and a plurality of second jigs JIG2 adjacent to the first jig JIG1. The first jig JIG1 and the second jigs JIG2 may be arranged to be in contact with each other in the first direction DR1 and the second direction DR2 while being in a state of being separated from each other.

The first plate PLT1 and the second plate PLT2 may be located below the jig JIG. The second plate PLT2 may be located below the first plate PLT1. Accordingly, the first plate PLT1 may be located between the jig JIG and the second plate PLT2.

The first plate PLT1 and the second plate PLT2 may have a plane defined by the first direction DR1 and the second direction DR2. The first plate PLT1 and the second plate PLT2 may extend longer in the first direction DR1 than in the second direction DR2.

The moving part MV may be located below the jig JIG. The moving part MV may include a first moving part MV1 and a plurality of second moving parts MV2. The first moving part MV1 and the second moving parts MV2 may have a cylindrical shape extending in the third direction DR3. The first moving part MV1 may have a larger diameter than each of the second moving parts MV2.

The first moving part MV1 may extend in the third direction DR3 and be located below the first jig JIG1. The second moving parts MV2 may extend in the third direction DR3 and be respectively located below the second jigs JIG2. The first moving part MV1 and the second moving parts MV2 may move back and forth in the third direction DR3. The third direction DR3 may be defined as an up-and-down direction.

The first moving part MV1 may be located below the first plate PLT1. The first moving part MV1 may be located in a hole H defined in the second plate PLT2. The first moving part MV1 may extend below the first plate PLT1 through the hole H.

According to some embodiments, the second moving parts MV2 may be respectively located below the second jigs JIG2 through holes defined in the first plate PLT1. This configuration will be illustrated in FIG. 9C below.

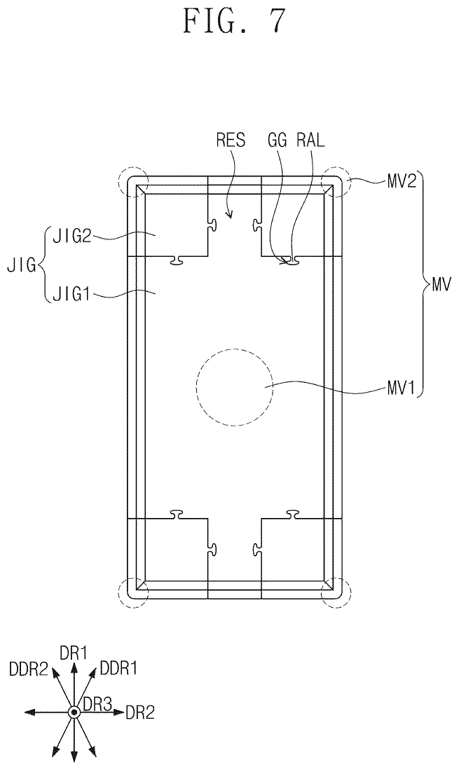

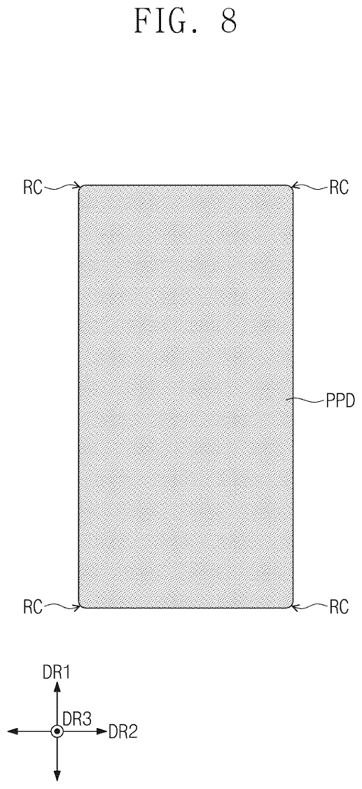

FIG. 6 is an exploded perspective view of the jig and the pressure pad illustrated in FIG. 5. FIG. 7 is a plan view of the jig illustrated in FIG. 6 and viewed from above. FIG. 8 is a plan view of the pressure pad illustrated in FIG. 6 and viewed from above.

As an example, in FIG. 6, the window fixing chuck FCK, the first and second plates PLT1 and PLT2, and the first and second moving parts MV1 and MV2 are omitted. In addition, as an example, in FIG. 7, the first and second moving parts MV1 and MV2 located below the jig are illustrated as dotted lines.

Referring to FIGS. 6 and 7, the second jigs JIG2 may be arranged in the first direction DR1 and the second direction DR2. As an example, four second jigs JIG2 may be arranged in two rows and two columns. The row may correspond to the second direction DR2, and the column may correspond to the first direction DR1. The second jigs JIG2 may respectively define the corners of the jig JIG.

In a plan view, the first jig JIG1 may have a cross shape and be located between the second jigs JIG2. In a plan view, the first jig JIG1 may be located between the second jigs JIG2 in the first direction DR1, the second direction DR2, a first diagonal direction DDR1, and a second diagonal direction DDR2.

The first diagonal direction DDR1 may be defined as a direction that crosses the first and second directions DR1 and DR2 on a plane defined by the first and second directions DR1 and DR2. The second diagonal direction DDR2 may be defined as a direction that crosses the first diagonal direction DDR1 on a plane defined by the first and second directions DR1 and DR2.

In a plan view, the first moving part MV1 may overlap the central portion of the first jig JIG1. In a plan view, the first moving part MV1 may be located between the second jigs JIG2 in the first diagonal direction DDR1 and the second diagonal direction DDR2.

The second jigs JIG2 may include a plurality of rail portions RAL protruding toward the first jig JIG1. The rail portions RAL may have a rail shape. The rail portions RAL may be inserted into guide grooves GG defined in the first jig JIG1. The rail portions RAL and the guide grooves GG may extend in the third direction DR3. The rail portions RAL may move in the third direction DR3 along the guide grooves GG.

In a plan view, the second moving parts MV2 may respectively overlap the second jigs JIG2. In a plan view, the second moving parts MV2 may respectively overlap the corners of the second jigs JIG2 that define the corners of the jig. In a plan view, portions of the second moving parts MV2 may be arranged to be more outside than the second jigs JIG2.

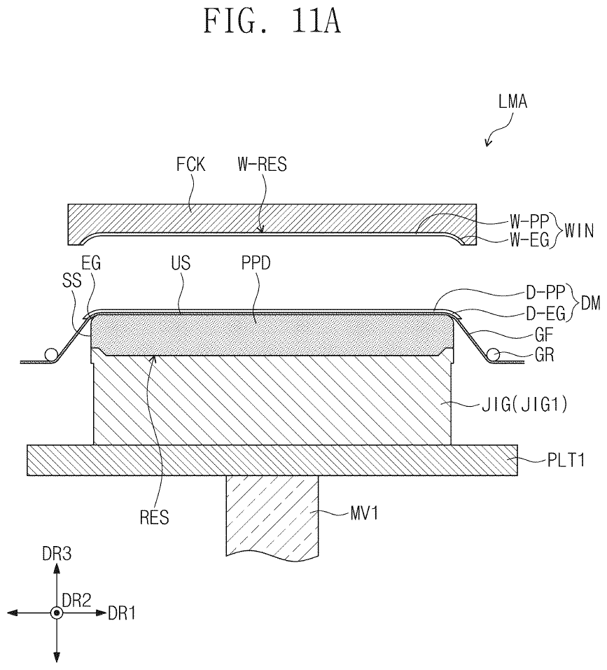

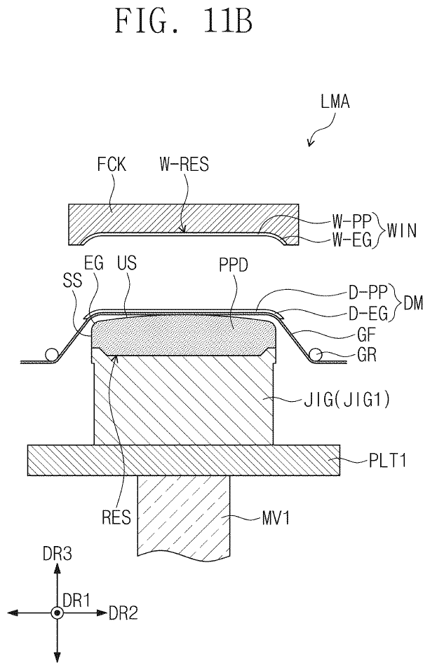

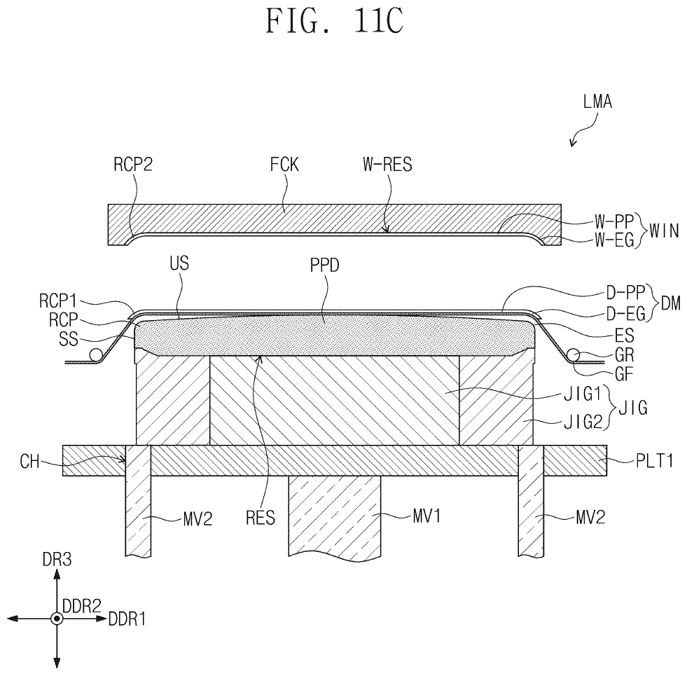

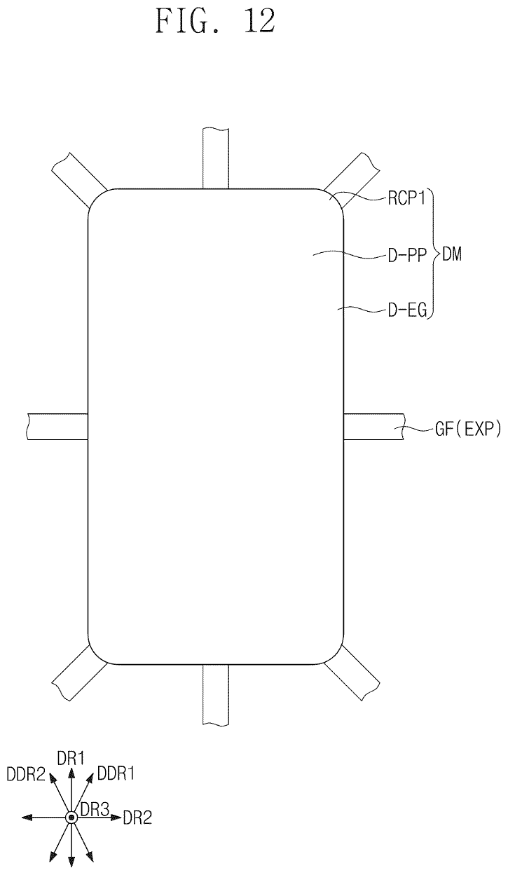

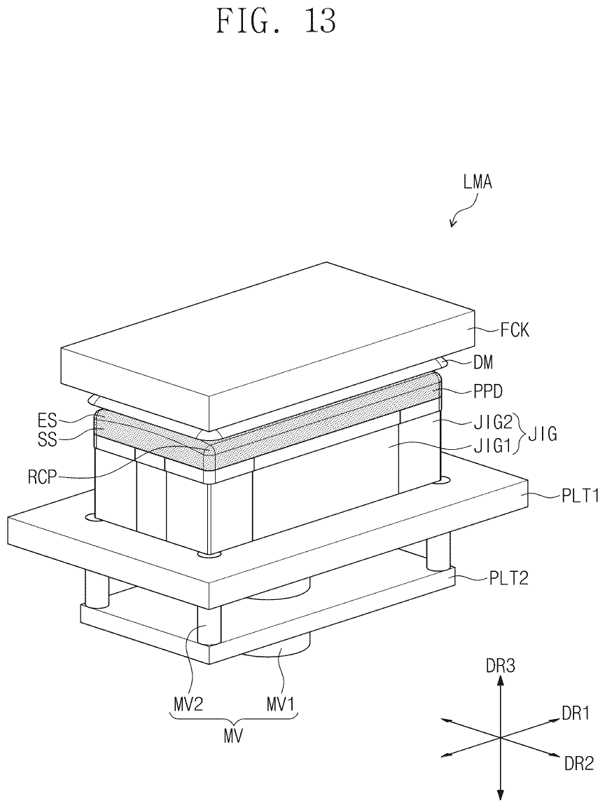

As the first and second moving parts MV1 and MV2 move back and forth in the third direction DR3, the first and second jigs JIG1 and JIG2 may move back and forth in the third direction DR3. This configuration will be described in detail below with reference to FIGS. 11A to 11C, 16A to 16C, and 19.

Referring to FIGS. 6 and 8, in a plan view, the pressure pad PPD may have a round-cornered tetragonal shape. For example, the pressure pad PPD may have long sides extending in the first direction DR1 and short sides extending in the second direction DR2. In addition, corners RC of the pressure pad PPD may have a curved shape.

The corners RC of the pressure pad PPD may be defined as round corners. The corners RC may be portions of the edges of the pressure pad PPD. Hereinafter, the corners RC are referred to as round corners RC.

FIG. 9A is a cross-sectional view taken along the line I-I′ illustrated in FIG. 6. FIG. 9B is a cross-sectional view taken along the line II-II′ illustrated in FIG. 6. FIG. 9C is a cross-sectional view taken along the line III-III′ illustrated in FIG. 6.

Referring to FIGS. 6 and 9A, in a view from the second direction DR2, an upper surface US of the pressure pad PPD may be parallel to the first direction DR1, and a side surface SS of the pressure pad PPD may be parallel to the third direction DR3. The lower surface of the pressure pad PPD may include a protruding portion PT protruding downward. A surface ES connecting the upper surface US and the side surface SS of the pressure pad PPD to each other may have a convex curved surface. The surface ES of the pressure pad PPD may be defined as a round edge.

Referring to FIGS. 6 and 9B, in a view from the first direction DR1, the height of the upper surface US of the pressure pad PPD in the third direction DR3 may gradually increase toward the central portion. The side surface SS of the pressure pad PPD may be parallel to the third direction DR3. The lower surface of the pressure pad PPD may include the protruding portion PT protruding downward. The surface ES connecting the upper surface US and the side surface SS of the pressure pad PPD to each other may have a convex curved surface and may be defined as a round edge.

Referring to FIGS. 6 and 9C, in a view from the second diagonal direction DDR2, the height of the upper surface US of the pressure pad PPD in the third direction DR3 may gradually increase toward the central portion. The side surface SS of the pressure pad PPD may be parallel to the third direction DR3. The lower surface of the pressure pad PPD may include the protruding portion PT protruding downward. The surface ES connecting the upper surface US and the side surface SS of the pressure pad PPD to each other may have a convex curved surface and be defined as a round edge.

According to some embodiments, the shape of the pressure pad PPD viewed from the first diagonal direction DDR1 may be the same as that of FIG. 9C.

Referring to FIGS. 6 and 9A to 9C, the pressure pad PPD may be coupled to the jig JIG. The protruding portion PT may be located in the recessed portion RES. The protruding portion PT may be attached to the upper surface of the jig JIG on which the recessed portion RES is defined. For example, the protruding portion PT may be attached, by an adhesive, to the upper surface of the jig JIG on which the recessed portion RES is defined.

Hereinafter, the surface ES of the pressure pad PPD having a curved surface is defined as a round edge surface ES. In a plan view, the round edge surface ES may surround the upper surface of the pressure pad PPD.

Referring to FIGS. 8 and 9C, portions of the pressure pad PPD including portions of the round edge surface ES corresponding to the round corners RC illustrated in FIG. 8 may be defined as round corner portions RCP. As an example, in FIG. 9C, the round corner portions RCP are illustrated as dotted lines.

FIG. 10 illustrates a state in which the display module is located on the pressure pad for a bonding process between the display module and the window.

Substantially, FIG. 10 may illustrate a preparation step, in which the display module DM and the window WIN (hereinafter illustrated in FIGS. 11A to 11C) are located, in a method of manufacturing the display device DD.

Referring to FIG. 10, the display module DM may be located on the pressure pad PPD. As described above, the display module DM may include a flat planar portion D-PP and an edge portion D-EG having a curved surface.

The window fixing chuck FCK may be located on the display module DM. Accordingly, the display module DM may be located between the window fixing chuck FCK and the pressure pad PPD.

In a plan view, the display module DM may have a round-cornered tetragonal shape. For example, the display module DM may have long sides extending in parallel to the first direction DR1 and short sides extending in parallel to the second direction DR2. In addition, the corners of the display module DM connecting the long and short sides of the display module DM to each other may have a curved shape and be defined as round corners. Portions of the edge portion D-EG of the display device DD, which correspond to the corners of the display module DM, may be defined as first round corner portions RCP1.

FIGS. 11A, 11B and 11C are cross-sectional views of the bonding device, which correspond to FIGS. 9A, 9B and 9C, in the preparation step illustrated in FIG. 10.

FIGS. 11A, 11B, and 11C are cross-sectional views illustrating the preparation step, in which the display module DM and the window WIN are located, in a method of manufacturing the display device DD. As an example, the second plate PLT2 is omitted in FIGS. 11A to 11C.

Referring to FIGS. 11A to 11C, a guide film GF may be located on the lower surface of the display module DM. The guide film GF may be in contact with the lower surface of the display module DM and extend more outside than the display module DM. As an example, the guide film GF is omitted in the perspective view of FIG. 10. The guide film GF is also omitted in perspective views to be illustrated below.

The guide film GF may be located on the pressure pad PPD. The display module DM may not be located directly on the pressure pad PPD, but may be located on the pressure pad PPD through the guide film GF. Accordingly, the guide film GF may be located between the pressure pad PPD and the display module DM.

The display module DM may be located on the guide film GF and moved onto the pressure pad PPD through the guide film GF. The position of the display module DM may be aligned by the guide film GF.

The guide film GF may come in contact with guide rollers GR outside the jig JIG. The guide rollers GR may be located on the guide film GF outside the jig JIG. The guide rollers GR may guide the position of the guide film GF outside the jig JIG.

The guide film GF may include a flexible plastic material. For example, the guide film GF may include a plastic material such as polyimide (PI) or polyethylene terephthalate (PET).

The planar portion D-PP of the display module DM may be located on the upper surface US of the pressure pad PPD. The edge portion D-EG of the display module DM may be located on the round edge surface ES of the pressure pad PPD.

A recessed portion W-RES may be defined on the lower surface of the window fixing chuck FCK. The window WIN may be located on the recessed portion W-RES. Accordingly, the window WIN may be located on the display module DM, and the window WIN may be arranged to face the display module DM. The window WIN located on the recessed portion W-RES may have a shape corresponding to the display module DM.

According to some embodiments, vacuum suction holes for adsorbing and fixing the window WIN may be defined on the inner surface of the window fixing chuck FCK on which the recessed portion W-RES is defined. In addition, according to some embodiments, an adhesive layer AL (illustrated in FIG. 2) for bonding the display module DM to the window WIN may be located on the display module DM.

Referring to FIG. 11C, in a plan view, portions of the window WIN, which correspond to the first round corner portions RCP1 of the display module DM, may be defined as second round corner portions RCP2. For example, the window WIN may have a round-cornered tetragonal shape, and portions of the edge portion W-EG of the window WIN, which correspond to the round corners of the window WIN, may be defined as second round corner portions RCP2. In a plan view, the second round corner portions RCP2 may respectively overlap the first round corner portions RCP1.

Referring to FIGS. 11A and 11B, the first moving part MV1 may be located below the first plate PLT1. The first moving part MV1 may be located below the central portion of the first plate PLT1.

Referring to FIGS. 11B and 11C, as the height of the upper surface US of the pressure pad PPD gradually increases toward the central portion, the central portion of the display module DM may first come in contact with the central portion of the upper surface US of the pressure pad PPD during a manufacturing process of the display device DD.

Referring to FIGS. 7 and 11C, the second moving parts MV2 may be respectively located below the second jigs JIG2. The second moving parts MV2 may be respectively located below the second jigs JIG2 through corner holes CH defined in the first plate PLT1.

The corner holes CH may respectively overlap the second jigs JIG2. The corner holes CH may respectively overlap the corners of the second jigs JIG2 that define the corners of the jig JIG. In a plan view, portions of the corner holes CH may be defined to be more outside than the second jigs JIG2.

FIG. 12 is a plan view of the display module and the guide film illustrated in FIGS. 11A to 11C and viewed from above.

Referring to FIG. 12, the guide film CF may be located below the display module DM and extend more outside than the display module DM. For example, the guide film CF may include a plurality of extension portions EXP extending more outside than the display module DM.

The extension portions EXP may extend in the first direction DR1 with respect to the short side of the display module DM and in the second direction DR2 with respect to the long side of the display module DM. In addition, the extension portions EXP may extend in the first diagonal direction DDR1 and the second diagonal direction DDR2 with respect to the first round corner portions RCP1 of the display module DM. As the extension portions EXP come in contact with the above-described guide rollers GR, the positions of the extension portions EXP may be guided.

FIG. 13 illustrates a state in which the window fixing chuck and the pressure pad are arranged to be adjacent to each other.

Referring to FIG. 13, in a method of manufacturing the display device DD, as the window fixing chuck FCK or the pressure pad PPD moves in the third direction DR3, the window fixing chuck FCK and the pressure pad PPD may be adjacent to each other in the third direction DR3.

According to some embodiments of the present disclosure, the window fixing chuck FCK may move in a downward direction and be arranged to be adjacent to the pressure pad PPD. Without being limited thereto, however, the pressure pad PPD, the jig JIG, the first and second plates PLT1 and PLT2, and the first and second moving parts MV1 and MV2 may move in an upward direction toward the window fixing chuck FCK. In addition, the window fixing chuck FCK, the pressure pad PPD, the jig JIG, the first and second plates PLT1 and PLT2, and the first and second moving parts MV1 and MV2 may move at the same time.

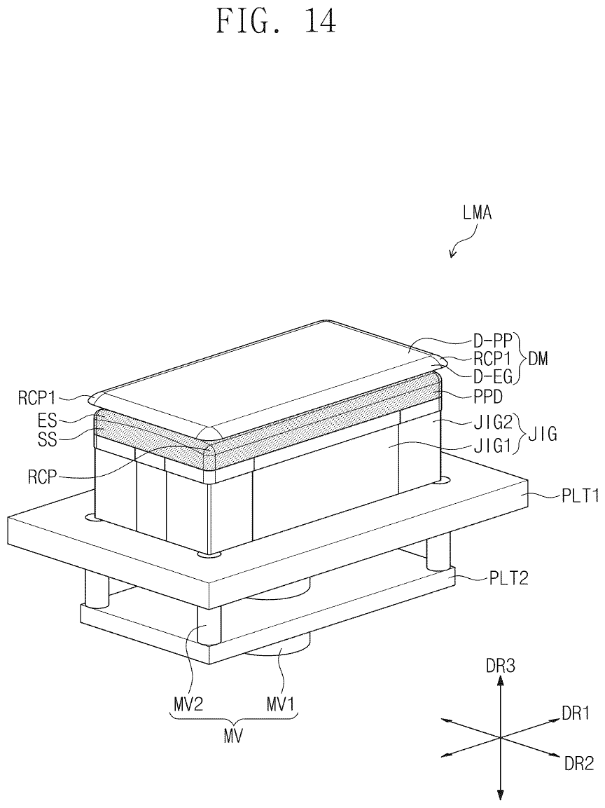

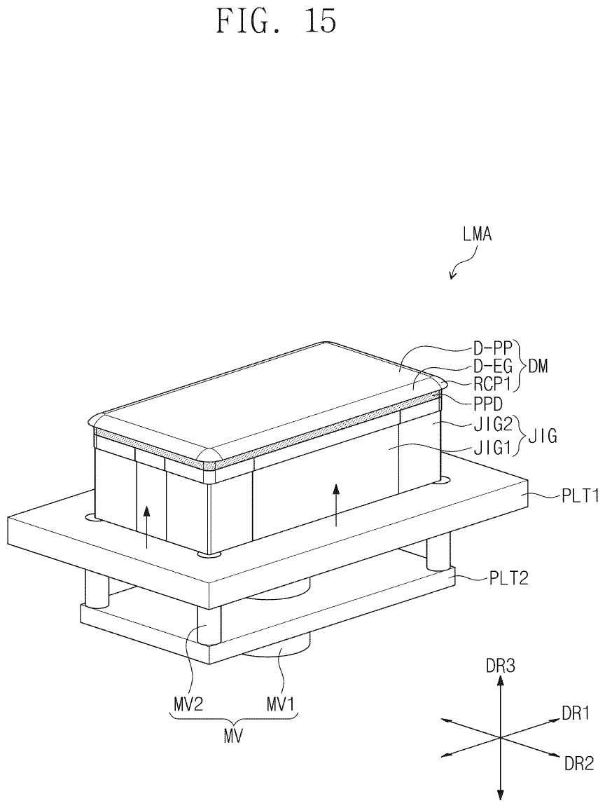

FIG. 14 is a view in which the window fixing chuck of FIG. 13 is omitted. FIG. 15 illustrates a first bonding process between the display module and the window by using a bonding device in a method of manufacturing the display device with the use of the bonding device.

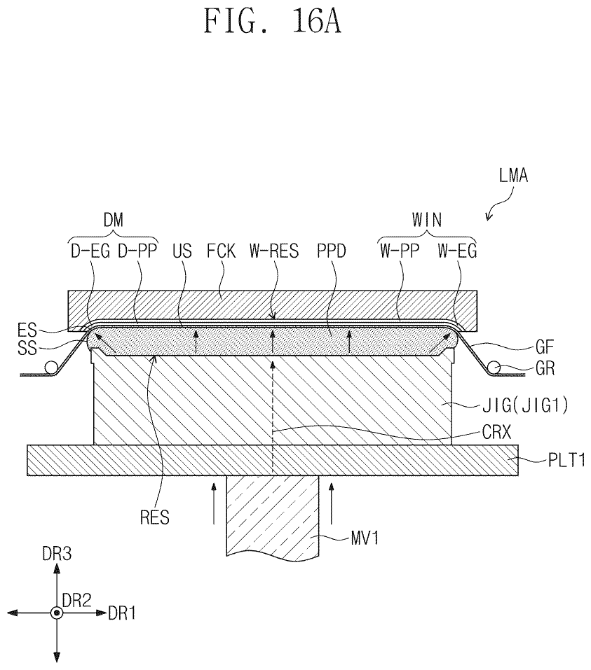

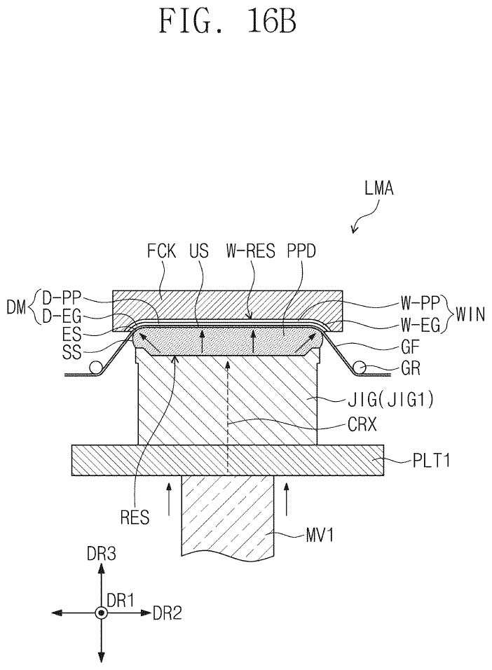

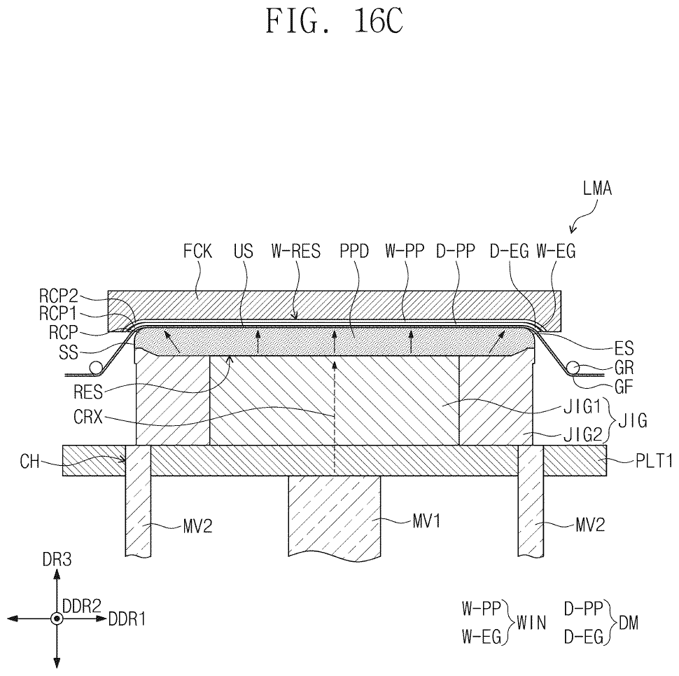

As an example, the window WIN and the window fixing chuck FCK are omitted in FIG. 15, and the window WIN and the window fixing chuck FCK will be illustrated in cross-sectional views of FIGS. 16A to 16C below.

Referring to FIGS. 14 and 15, as the first moving part MV1 moves upward, the first plate PLT1 may move upward. As a result, the jig JIG may move upward and press the pressure pad PPD. The pressed pressure pad PPD may press the display module DM toward the window WIN.

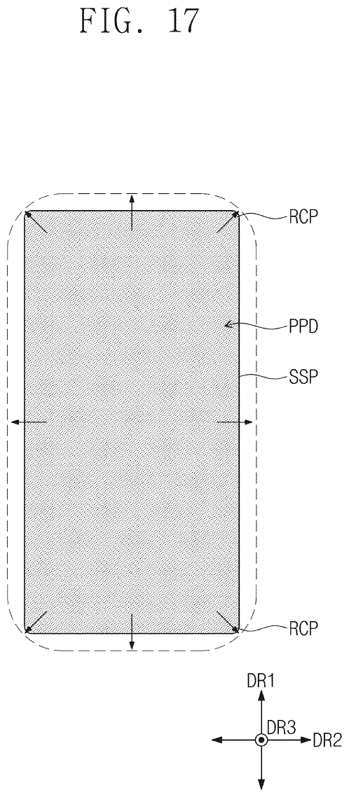

FIGS. 16A, 16B, and 16C are cross-sectional views of the bonding device, which correspond to FIGS. 11A, 11B, and 11C, in the first bonding process illustrated in FIG. 15. FIG. 17 is a plan view illustrating a deformed state of the pressure pad in the first bonding process illustrated in FIGS. 16A, 16B, and 16C.

Referring to FIGS. 16A, 16B, and 16C, as the first moving part MV1 moves upward, the first plate PLT1 may move the jig JIG upward. The first plate PLT1 may move the first jig JIG1 and the second jigs JIG2, which are located on the first plate PLT1, in an upward direction.

The first moving part MV1 located in the central portion of the first jig JIG1 may move upward. Accordingly, during a pressing operation according to the movement of the first moving part MV1, a central pressing axis CRX may be defined in the central portion of the first jig JIG1. The central pressing axis CRX defined in the first jig JIG1 may overlap the central axis of the first moving part MV1. The central axis of the first moving part MV1 may be defined as the central point of a circle in the cross-sectional circle of the first moving part MV1, which has a cylindrical shape.

The jig may move upward to press the pressure pad PPD, and the pressed pressure pad PPD may transmit a pressure (e.g., a set or predetermined pressure) to the display module DM. Accordingly, the display module DM may be pressed toward the window WIN by the pressure pad PPD. As a result, the display module DM may be bonded to the window WIN.

Referring to FIGS. 11B, 11C, 16B, and 16C, as the height of the upper surface US of the pressure pad PPD gradually increases toward the central portion, the central portion of the display module DM may be first bonded to the central portion of the window WIN during the first bonding process. Hereafter, the display module DM may be gradually bonded to the window WIN from the central portion of the display module DM to the ends of the planar portion D-PP of the display module DM.

Referring to FIGS. 16A to 16C, the planar portion D-PP of the display module DM may first be bonded to the planar portion W-PP of the window WIN by the pressure pad PPD.

Referring to FIG. 17, when the pressure pad PPD is pressed, the expansion forces of the side portions SSP and the round corner portions RCP corresponding to the long and short sides of the pressure pad PPD may be different from each other. The side portions SSP of the pressure pad PPD may expand more outward than those of the round corner portions RCP. As an example, in FIG. 17, the expanded state of the pressure pad PPD is illustrated as a dotted line.

Referring to FIGS. 16A, 16B, and 17, the side portions SSP of the pressure pad PPD may expand further outward. In this case, after the planar portion D-PP of the display module DM is pressed against the planar portion W-PP of the window WIN, the edge portion D-EG of the module DM may be pressed toward the edge portion W-EG of the window WIN by the side portions SSP of the expanded pressure pad PPD. Accordingly, the edge portion D-EG of the display module DM may be bonded to the edge portion W-EG of the window WIN.

Referring to FIGS. 16C and 17, the round corner portions RCP of the pressure pad PPD may expand less outward than the side portions SSP of the pressure pad PPD. In this case, since the round corner portions RCP of the pressure pad PPD do not expand sufficiently, the first round corner portions RCP1 of the display module DM may not be bonded to the second round corner portions RCP2 of the window WIN.

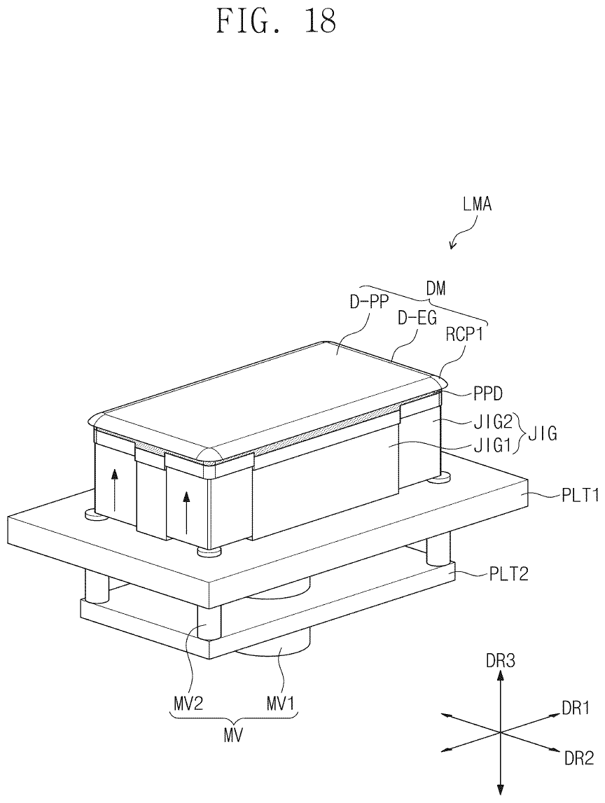

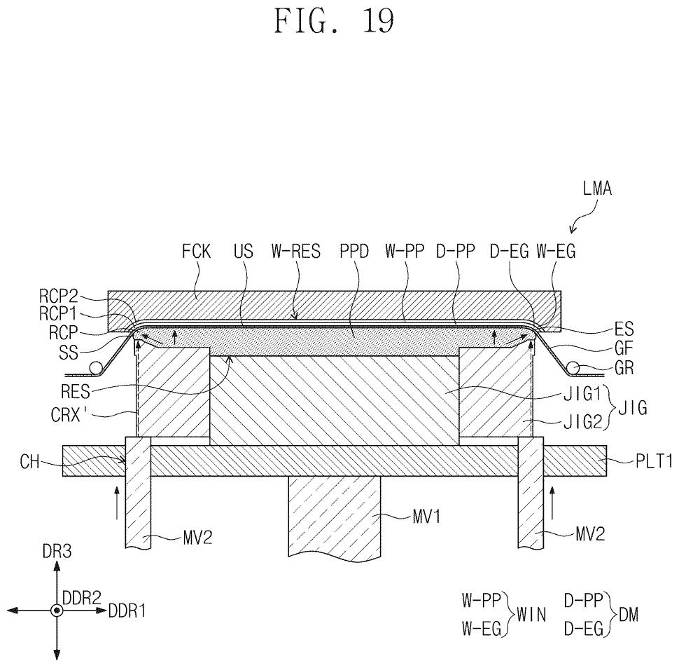

FIG. 18 illustrates a second bonding process between the display module and the window by using the bonding device in a method of manufacturing the display device with the use of the bonding device. FIG. 19 is a cross-sectional view of the bonding device, which corresponds to FIG. 16C, in the second bonding process illustrated in FIG. 18.

As an example, the window WIN and the window fixing chuck FCK are omitted in the second bonding process of FIG. 18, and the window WIN and the window fixing chuck FCK will be illustrated in a cross-sectional view of FIG. 19 below.

Referring to FIGS. 18 and 19, the second moving parts MV2 may move upward through the corner holes CH. The second moving parts MV2 may further move the second jigs JIG2 in an upward direction separately from the first moving part MV1.

In a plan view, the second jigs JIG2 may overlap the round corner portions RCP of the pressure pad PPD. The round corner portions RCP may be pressed by the second jigs JIG2. The pressed round corner portions RCP may expand outward while contracting in the third direction DR3.

The pressed round corner portions RCP may press the first round corner portions RCP1 of the display module DM toward the second round corner portions RCP2 of the window WIN. Accordingly, the first round corner portions RCP1 may be bonded to the second round corner portions RCP2 by the pressed round corner portions RCP.

As described above, in a plan view, portions of the second moving parts MV2 may be arranged to be more outside than the second jigs JIG2. According to this structure, in a plan view, the second moving parts MV2 may overlap the round corner portions RCP. Accordingly, when the second moving parts MV2 move upward, the second jigs JIG2 may further press the round corner portions RCP.

During a pressing operation according to the movement of the second moving parts MV2, corner pressing axes CRX′ may be respectively defined in the second jigs JIG2. As described above, as the second jigs JIG2 define the corners of the jig JIG, the corner pressing axes CRX′ may be adjacent to the corners of the jig JIG.

The corner pressing axes CRX′ may respectively overlap the central axes of the second moving parts MV2. Each of the central axes of the second moving parts MV2 may be defined as the central point of a circle in the cross-sectional circle of each of the second moving parts MV2, which has a cylindrical shape. In a plan view, the corner pressing axes CRX′ may respectively overlap the round corner portions RCP.

Since the corner pressing axes CRX′ respectively overlap the round corner portions RCP, the round corner portions RCP may be further pressed. Accordingly, the first round corner portions RCP1 may be more easily bonded to the second round corner portions RCP2.

After the second bonding process for the display module DM and the window WIN is completed, as the second moving parts MV2 move downward, the second jigs JIG2 may move downward. That is, the second moving parts MV2 may move the second jigs JIG2 in an up-and-down direction separately from the first moving part MV1.

Next, as the first moving part MV1 and the second moving parts MV2 move downward, the first jig JIG1 and the second jigs JIG2 may move downward. Accordingly, the jig may be restored to its original position, and the bonding process for the display module DM and window WIN may be completed.

According to some embodiments of the present disclosure, when the display module DM and the window WIN are bonded to each other, firstly, as the pressure pad PPD is pressed through the jig JIG, a portion of the display module DM except the first round corner portions RCP1 of the display module DM may be bonded to the window WIN.

Hereafter, secondly, as the second jigs JIG2 move upward, the round corner portions RCP of the pressure pad PPD may be additionally pressed. The first round corner portions RCP1 of the display module DM may be bonded to the second round corner portions RCP2 of the window WIN by the additionally pressed round corner portions RCP. Therefore, the display module DM and the window WIN may be normally bonded to each other, while preventing or reducing bonding defects between them.

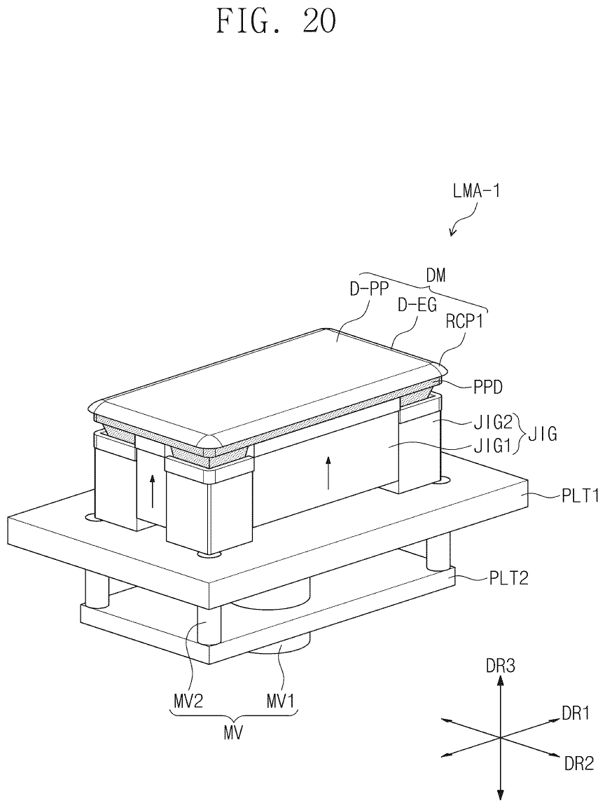

FIG. 20 illustrates a first bonding process by using a bonding device according to some embodiments of the present disclosure.

As an example, FIG. 20 is a perspective view corresponding to FIG. 15. Hereinafter, the configuration of a bonding device LMA-1 and a method of manufacturing the display device DD by using the bonding device LMA-1 will be described, focusing on components different from those of the bonding device LMA.

Referring to FIG. 20, when a first bonding process is performed by the bonding device LMA-1, the second moving parts MV2 may not move and the first moving part MV1 may move upward. Accordingly, the second jigs JIG2 may not move, and the first jig JIG1 may move upward.

A portion of the pressure pad PPD overlapping the first jig JIG1 may be moved upward by the first jig JIG1. The second jigs JIG2 do not move, but as the pressure pad PPD is formed integrally, portions of the pressure pad PPD that overlap the second jigs JIG2 may also move upward together when the portion of the pressure pad PPD overlapping the first jig JIG1 moves upward.

As illustrated in FIG. 20, when portions of the pressure pad PPD overlapping the second jigs JIG2 move upward, the portions of the pressure pad PPD overlapping the second jigs JIG2 may be stretched upward in a state of being attached to the second jigs JIG2.

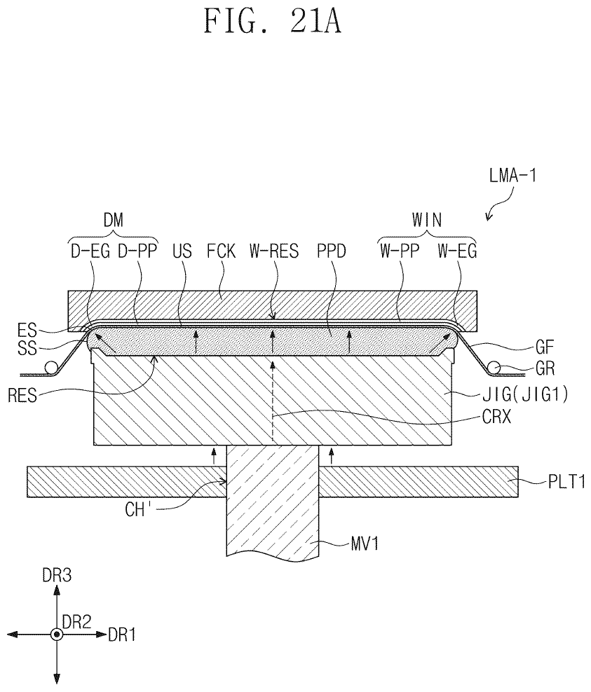

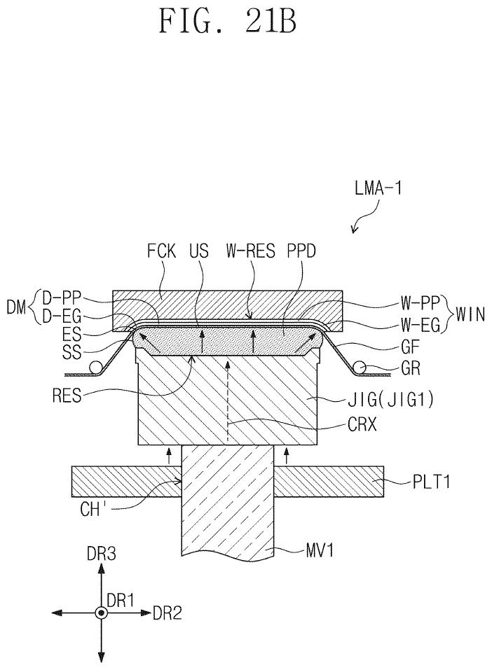

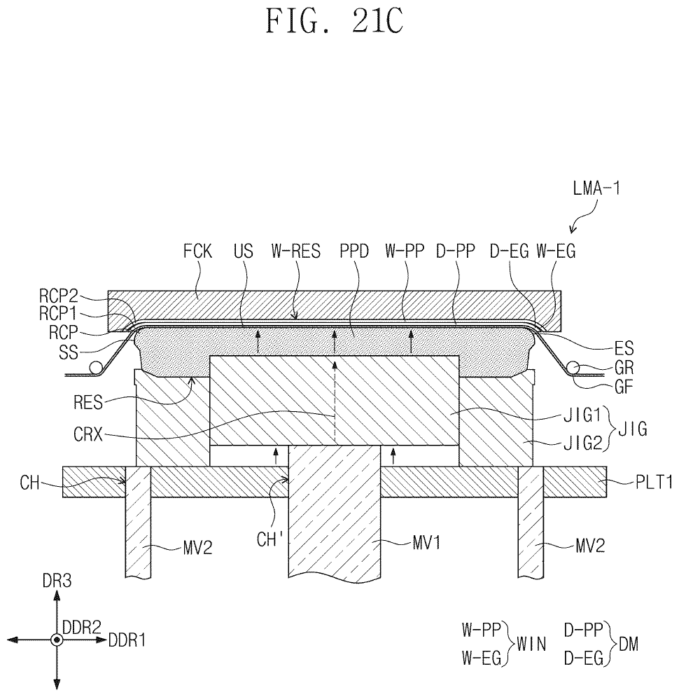

FIGS. 21A, 21B, and 21C are cross-sectional views of the bonding device, which correspond to FIGS. 16A, 16B, and 16C, in the first bonding process illustrated in FIG. 20.

Referring to FIGS. 21A, 21B, and 21C, a central hole CH′ may be defined in the first plate PLT1. The central hole CH′ may overlap the first moving part MV1. The first moving part MV1 may be located in the central hole CH′. The first moving part MV1 may be located below the first jig JIG1 through the central hole CH′.

The first moving part MV1 may move upward through the central hole CH′ and move the first jig JIG1 upward. The first plate PLT1 and the second moving parts MV2 may not move upward, and the positions of the first plate PLT1 and the second moving parts MV2 may be fixed. Accordingly, the second jigs JIG2 may not move upward, and the positions of the second jigs JIG2 may be fixed.

The display module DM may be pressed toward the window WIN by the pressure pad PPD. The planar portion D-PP of the display module DM may first be bonded to the planar portion W-PP of the window WIN by the pressing pad PPD.

Referring to FIGS. 21A and 21B, the edge portion D-EG of the display module DM may be pressed toward the edge portion W-EG of the window WIN by the side portions SSP of the expanded pressure pad PPD. Accordingly, the edge portion D-EG of the display module DM may be bonded to the edge portion W-EG of the window WIN.

Referring to FIG. 21C, since the round corner portions RCP of the pressure pad PPD do not expand sufficiently, the first round corner portions RCP1 of the display module DM may not be bonded to the second round corner portions RCP2 of the window WIN.

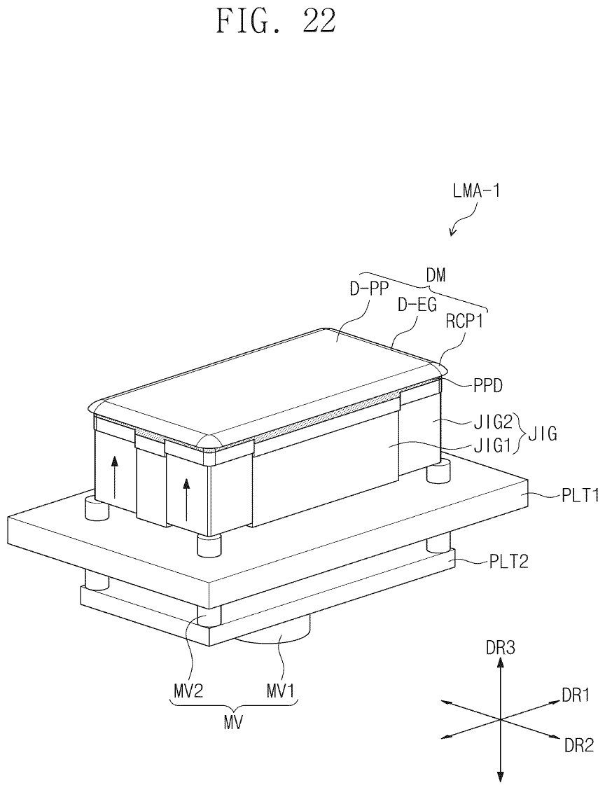

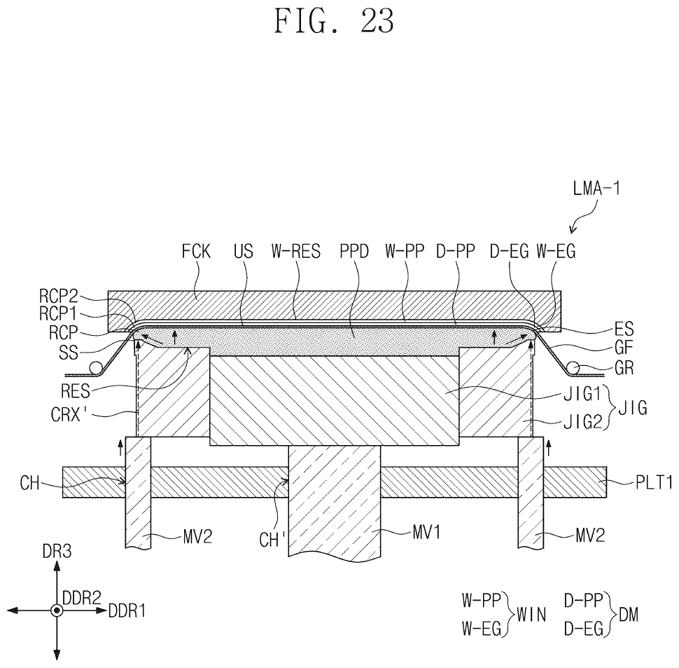

FIG. 22 illustrates a second bonding process by using the bonding device according to some embodiments of the present disclosure. FIG. 23 is a cross-sectional view of the bonding device, which corresponds to FIG. 21C, in the second bonding process illustrated in FIG. 22.

As an example, FIG. 22 is a perspective view corresponding to FIG. 18.

Referring to FIGS. 22 and 23, the second moving parts MV2 may move upward through the corner holes CH. The second jigs JIG2 may be moved upward by the second moving parts MV2. The second jigs JIG2 may move higher than the first jig JIG1. Accordingly, the second jigs JIG2 may further press the round corner portions RCP of the pressure pad PPD.

The pressed round corner portions RCP may press the first round corner portions RCP1 of the display module DM toward the second round corner portions RCP2 of the window WIN. Accordingly, the first round corner portions RCP1 of the display module DM may be more easily bonded to the second round corner portions RCP2 of the window WIN.

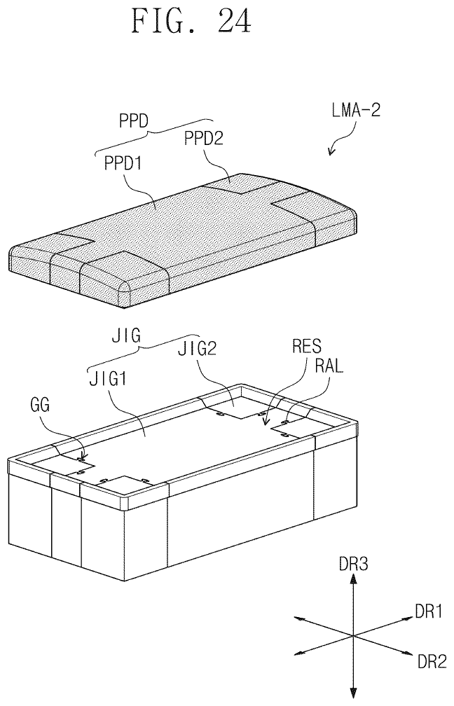

FIG. 24 illustrates the configuration of a bonding device according to some embodiments of the present disclosure.

As an example, FIG. 24 is an exploded perspective view corresponding to FIG. 6. Hereinafter, the configuration of a bonding device LMA-2 will be described, focusing on components different from those of the bonding device LMA illustrated in FIG. 6.

Referring to FIG. 24, the pressure pad PPD may include a first pressure pad PPD1 and a plurality of second pressure pads PPD2. The first pressure pad PPD1 and the second pressure pads PPD2 may be arranged to be separated from and come in contact with each other.

In a plan view, the first pressure pad PPD1 may overlap the first jig JIG1. In a plan view, the second pressure pads PPD2 may respectively overlap the second jigs JIG2. The first pressure pad PPD1 may be moved by the first jig JIG1. The second pressure pads PPD2 may be moved by the second jigs JIG2.

The first pressure pad PPD1 may have a shape corresponding to that of the first jig JIG1. The second pressure pads PPD2 may have a shape corresponding to that of the second jigs JIG2. The hardness of each of the second pressure pads PPD2 may be greater than that of the first pressure pad PPD1. As an example, the hardness of the first pressure pad PPD1 may be about 16, and the hardness of the second pressure pads PPD2 may be about 19 to about 21. Accordingly, the second pressure pads PPD2 may have greater elasticity than the first pressure pad PPD1.

When the second pressure pads PPD2, which have greater elasticity, are contracted, pressure may be better transmitted to an object to be pressed. That is, when the elasticity of the second pressure pads PPD2 is high, pressure may be better transmitted to the first round corner portions RCP1 of the display module DM in the second pressure process illustrated in FIGS. 19 and 23. As a result, the first round corner portions RCP1 may be more easily bonded to the second round corner portions RCP2.

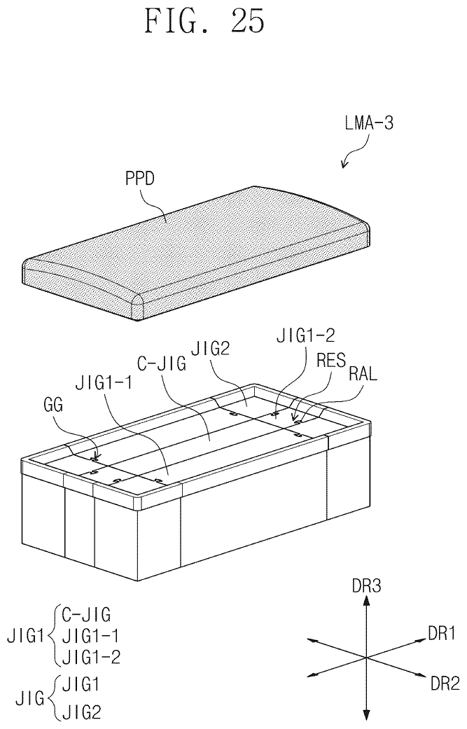

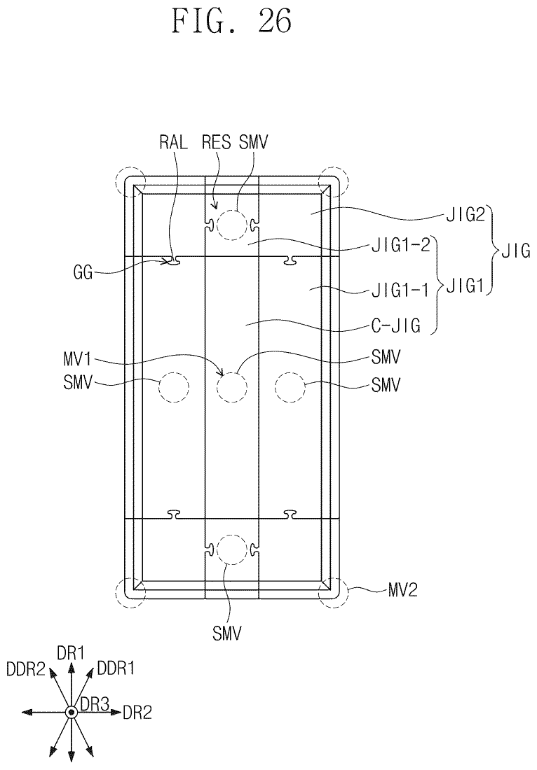

FIG. 25 illustrates the configuration of a bonding device according to some embodiments of the present disclosure. FIG. 26 is a plan view of the jig illustrated in FIG. 25 and viewed from above.

As an example, FIG. 25 is an exploded perspective view corresponding to FIG. 6. Hereinafter, the configuration of a bonding device LMA-3 will be described, focusing on components different from those of the bonding device LMA illustrated in FIG. 6. As an example, in FIG. 26, the first and second moving parts MV1 and MV2 located below the jig JIG are illustrated as dotted lines.

Referring to FIGS. 25 and 26, the first jig JIG1 may include a plurality of (1-1)-th jigs JIG1-1, a plurality of (1-2)-th jigs JIG1-2, and a central jig C-JIG. The (1-1)-th jigs JIG1-1 may be located between the second jigs JIG2 arranged in the first direction DR1. The (1-2)-th jigs JIG1-2 may be located between the second jigs JIG2 arranged in the second direction DR2. The central jig C-JIG may be located between the (1-1)-th jigs JIG1-1 and the (1-2)-th jigs JIG1-2.

The first moving part MV1 may include a plurality of sub-moving parts SMV. The sub-moving parts SMV may be respectively located below the (1-1)-th jigs JIG1-1, the (1-2)-th jigs JIG1-2, and the central jig C-JIG. According to some embodiments, holes overlapping the (1-1)-th jigs JIG1-1, the (1-2)-th jigs JIG1-2, and the central jig C-JIG may be defined in the first plate PLT1. The sub-moving parts SMV may be respectively located below the (1-1)-th jigs JIG1-1, the (1-2)-th jigs JIG1-2, and the central jig C-JIG through the holes.

The second jigs JIG2, the (1-1)-th jigs JIG1-1, the (1-2)-th jigs JIG1-2, and the central jig C-JIG may be individually moved up and down by the second moving parts MV2 and the sub-moving parts SMV. The central jig C-JIG may first move upward, and then the (1-1)-th jigs JIG1-1 and the (1-2)-th jigs JIG1-2 may move upward. Hereafter, the second jigs JIG2 may move upward.

According to some embodiments of the present disclosure, firstly, when the display module and the window are bonded to each other, the pressure pad is pressed through the jig so that a portion of the display module excluding the first round corner portions of the display module may be bonded to the window. Hereafter, secondly, the second jigs are moved upward to further press the round corner portions of the pressure pad so that the first round corner portions of the display module may be bonded to the second round corner portions of the window. Therefore, the display module and the window may be normally bonded to each other, while preventing or reducing bonding defects between the display module and the window.

Although the above has been described with reference to some embodiments of the present disclosure, those skilled in the art or those of ordinary skill in the art will understand that various modifications and changes can be made to the embodiments according to the present disclosure within the scope that does not depart from the spirit and scope of embodiments according to the present disclosure described in the claims to be described later. Accordingly, the technical scope of embodiments according to the present disclosure should not be limited to the content described in the detailed description of the specification, but should be determined by the claims described hereinafter.

What is claimed is:

1. A bonding device comprising:
a pressure pad;
a jig below the pressure pad; and
a moving part below the jig,
wherein the jig comprises:
a first jig; and
a plurality of second jigs adjacent to the first jig, and
wherein the moving part comprises:
a first moving part below the first jig; and
a plurality of second moving parts respectively below the second jigs.

2. The bonding device of claim 1, wherein the plurality of second jigs respectively define corners of the jig.

3. The bonding device of claim 2, wherein, in a plan view, the second moving parts respectively overlap the corners of the second jigs that define the corners of the jig.

4. The bonding device of claim 1, wherein, in a plan view, the first moving part overlaps a central portion of the first jig.

5. The bonding device of claim 1, wherein the second moving parts move the second jigs in an up-and-down direction separately from the first moving part.

6. The bonding device of claim 1, wherein, in a plan view, the pressure pad has a round-cornered tetragonal shape.

7. The bonding device of claim 1, wherein the first jig has a cross shape.

8. The bonding device of claim 1, wherein:
the second jigs are arranged in a first direction and a second direction crossing the first direction; and
the first jig is between the second jigs in the first direction, the second direction, a first diagonal direction, and a second diagonal direction,
wherein:
the first diagonal direction is defined as a direction that crosses the first and second directions in a plan view; and
the second diagonal direction is defined as a direction that crosses the first diagonal direction in the plan view.

9. The bonding device of claim 8, wherein:
in the plan view, the pressure pad has long sides extending in parallel to the first direction and short sides extending in parallel to the second direction;
in a view from the second direction, an upper surface of the pressure pad is parallel to the first direction;
in a view from the first direction, a height of the upper surface of the pressure pad gradually increases toward a central portion; and
in a view from the first diagonal direction and the second diagonal direction, the height of the upper surface of the pressure pad gradually increases toward the central portion.

10. The bonding device of claim 8, wherein, in a view from the first direction, the second direction, the first diagonal direction, and the second diagonal direction, a round edge surface connecting an upper surface and a side surface of the pressure pad to each other has a curved surface.

11. The bonding device of claim 1, further comprising a plate below the jig.

12. The bonding device of claim 11, wherein the first moving part is below the plate.

13. The bonding device of claim 11, wherein the first moving part is below the first jig through a central hole defined in the plate.

14. The bonding device of claim 11, wherein the second moving parts are respectively below the second jigs through corner holes defined in the plate.

15. The bonding device of claim 1, wherein the pressure pad comprises:
a first pressure pad overlapping the first jig in a plan view; and
a plurality of second pressure pads respectively overlapping the second jigs in the plan view.

16. The bonding device of claim 15, wherein a hardness of each of the second pressure pads is greater than that of the first pressure pad.

17. The bonding device of claim 1, wherein the second jigs are arranged in a first direction and a second direction crossing the first direction, and wherein the first jig comprises:
a plurality of (1-1)-th jigs between the second jigs in the first direction;
a plurality of (1-2)-th jigs between the second jigs in the second direction; and
a central jig between the (1-1)-th jigs and between the (1-2)-th jigs.

18. The bonding device of claim 17, wherein the first moving part comprises a plurality of sub-moving parts below the (1-1)-th jigs, the (1-2)-th jigs, and the central jig.

19. The bonding device of claim 1, further comprising a guide film on a rear surface of a display module on the pressure pad,
wherein the guide film comprises a plurality of extension portions extending more outside than the display module.

20. A bonding device comprising:
a pressure pad; and
a jig below the pressure pad,
wherein the jig presses the pressure pad, and
wherein the jig comprises:
a first jig, which moves in an up-and-down direction and defines a central pressing axis corresponding to a pressing location of the pressure pad; and
a plurality of second jigs which respectively define corners of the jig, move in an up-and-down direction, and define corner pressing axes adjacent to the corners of the jig corresponding to the pressing location of the pressure pad.

21. A method of manufacturing a display device, the method comprising:
arranging a display module on a pressure pad on a jig comprising a first jig and a plurality of second jigs adjacent to the first jig;
arranging a window on the display module;
moving the jig upward to press the pressure pad and bonding the display module to the window; and
moving the second jigs further upward to press round corner portions of the pressure pad overlapping the second jigs and bonding first round corner portions of the display module to second round corner portions of the window.
